(19) United States
(12) Patent Application Publication
(10) Pub. No.: US 2026/0371861 A1
(43) Pub. Date: Nov. 19, 2026

(54) PIXEL CIRCUIT BOARD, DISPLAY DEVICE, AND METHOD OF MANUFACTURING PIXEL CIRCUIT BOARD

(71) Applicant: Sharp Display Technology Corporation, Kameyama City, Mie (JP)

(72) Inventor: Masatomo HONJO, Kameyama City, Mie (JP)

(21) Appl. No.: 19/150,262

(22) PCT Filed: Jan. 27, 2023
(86) PCT No.: PCT/JP2023/002654

§ 371 Date: Jul. 23, 2025

(51) Int. Cl. H10K 59/124; G09G 3/3225; H10K 59/12; H10K 59/121

(52) U.S. Cl. CPC H10K 59/124; G09G 3/3225; H10K 59/1201; H10K 59/1213; G09G 2300/0426

(57) ABSTRACT

A pixel circuit board includes a plurality of pixel circuits each including a first electrode and a second electrode forming a capacitance. The pixel circuit board further includes a first insulation film and a second insulation film. The first electrode is formed in an underlying layer of the first insulation film, the second electrode is formed on the first insulation film, the second insulation film is formed on the second electrode, the first insulation film has a lower etching rate to a prescribed etchant than does the second insulation film, and a first contact hole overlapping the second electrode in a plan view and a second contact hole overlapping the first electrode in a plan view are formed in the second insulation film.

### TECHNICAL FIELD

The disclosure relates to pixel circuit boards, display devices, and methods of manufacturing pixel circuit boards.

### BACKGROUND ART

Patent Literature 1 describes a semiconductor device including: a capacitive element including a nitride film in a capacitive insulation film; a diffusion layer; and a silicide layer formed on the diffusion layer, wherein the nitride film covers the silicide layer.

### CITATION LIST

### Patent Literature

Patent Literature 1: Japanese Unexamined Patent Application Publication No. 2003-282726

### SUMMARY

### Technical Problem

The semiconductor device described in Patent Literature 1 has a problem that if an electrode of the capacitive element and a contact hole are designed in response to demands for high definition, the contact hole ends up being designed beyond alignment precision limits so that the contact hole does not sit squarely on the electrode. That in turn leads to short-circuiting of these two capacitance-forming electrodes, which impairs the function of the capacitive element.

The present disclosure, directed to a pixel circuit board in an aspect thereof, has been made in view of these problems and has an object to provide a pixel circuit board and related art that enable reducing the possibility of the contact hole failing to sit squarely on an electrode of the capacitive element and hence allowing for a high definition design.

### Solution to Problem

The present disclosure, in an aspect thereof, is directed to a pixel circuit board including a plurality of pixel circuits each including a first electrode and a second electrode forming a capacitance, the pixel circuit board further including a first insulation film and a second insulation film, wherein the first electrode is formed in an underlying layer of the first insulation film, the second electrode is formed on the first insulation film, the second insulation film is formed on the second electrode, the first insulation film has a lower etching rate to a prescribed etchant than does the second insulation film, and a first contact hole overlapping the second electrode in a plan view and a second contact hole overlapping the first electrode in a plan view are formed in the second insulation film.

The present disclosure, in another aspect thereof, is directed to a display device including: a pixel circuit board in accordance with an aspect of the present disclosure; and a light-emitting element layer disposed on the pixel circuit board.

The present disclosure, in another aspect thereof, is directed to a method of manufacturing a pixel circuit board including a pixel circuit including a first electrode and a second electrode forming a capacitance, the method including: a step of forming the first electrode; a step of forming a first insulation film on the first electrode; a step of forming the second electrode on the first insulation film; a step of forming a second insulation film on the second electrode; a step of forming a first contact hole overlapping the second electrode in a plan view by etching the second insulation film using an etchant; and a step of forming a second contact hole overlapping the first electrode in a plan view by etching the second insulation film using the etchant, wherein the first insulation film has a lower etching rate to the etchant than does the second insulation film.

### Advantageous Effects of Disclosure

The present disclosure, in an aspect thereof, can provide a pixel circuit board and related art that enable reducing the possibility of a contact hole failing to sit squarely on an electrode of a capacitive element and hence allowing for a high definition design.

### BRIEF DESCRIPTION OF DRAWINGS

FIG. 1 is a schematic cross-sectional view of a display device 500 including a pixel circuit board 200 in accordance with an aspect of the present disclosure.

FIG. 2 is a schematic cross-sectional view of a display device 501 including a pixel circuit board 201 in accordance with an aspect of the present disclosure.

FIG. 3 is a schematic cross-sectional view of a capacitor (capacitive element) 101 included in a pixel circuit board in accordance with an aspect of the present disclosure.

FIG. 4 is a schematic top view of the capacitor (capacitive element) 101 included in a pixel circuit board in accordance with an aspect of the present disclosure.

FIG. 5 is a schematic cross-sectional view of a capacitor (capacitive element) 102 included in a pixel circuit board in accordance with an aspect of the present disclosure.

FIG. 6 is a schematic cross-sectional view of a capacitor (capacitive element) 103 included in a pixel circuit board in accordance with an aspect of the present disclosure.

FIG. 7 is a schematic cross-sectional view of a capacitor (capacitive element) 104 included in a pixel circuit board in accordance with an aspect of the present disclosure.

FIG. 8 is a schematic cross-sectional view of a second electrode 12a of a capacitor (capacitive element) included in a pixel circuit board in accordance with an aspect of the present disclosure.

FIG. 9 is a schematic diagram illustrating a step of forming a first electrode 11, a step of forming a first insulation film 21, and a step of forming a second electrode 12b, all steps included in a method of manufacturing a pixel circuit board in accordance with an aspect of the present disclosure.

FIG. 10 is a schematic diagram illustrating a step of etching included in a method of manufacturing a pixel circuit board in accordance with an aspect of the present disclosure and performed while the second electrode 12b is being protected by a resist 700.

FIG. 11 is a schematic diagram illustrating a step of forming a first contact hole 31 and a step of forming a second contact hole 32, both included in a method of manufacturing a pixel circuit board in accordance with an aspect of the present disclosure.

FIG. 12 is a schematic diagram illustrating a capacitor 105 included in a pixel circuit board manufactured by a method of manufacturing a pixel circuit board in accordance with an aspect of the present disclosure.

### DESCRIPTION OF EMBODIMENTS

### Display Device 500

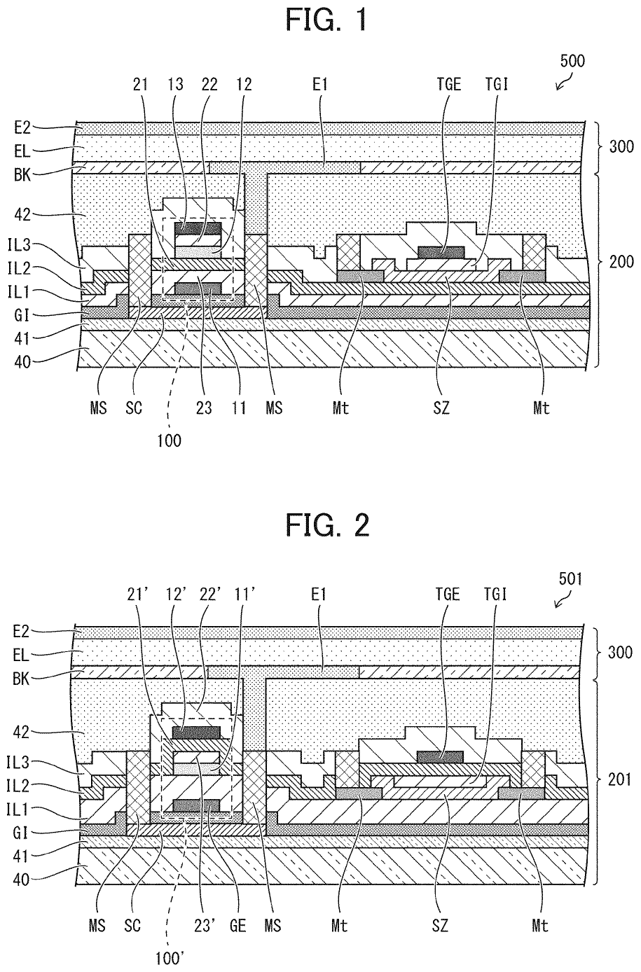

FIG. 1 is a schematic cross-sectional view of a display device 500 in accordance with an aspect of the present disclosure. The display device 500 in accordance with an aspect of the present disclosure includes a pixel circuit board 200 in accordance with an aspect of the present disclosure and a light-emitting element layer 300 disposed on the pixel circuit board.

Referring to FIG. 1, the pixel circuit board 200 includes a capacitor (capacitive element) 100 in a first pixel circuit, includes an undercoat film 41, a semiconductor film SC, a gate insulation film GI, an insulation film IL1, an insulation film IL2, and an insulation film IL3, all formed on a main substrate 40; and includes an organic insulation film (alternatively referred to as a “planarization film”) 42 formed on the insulation film IL3. Here, the capacitor 100 includes: a first electrode 11 provided between the gate insulation film GI and the insulation film IL1; a second electrode 12 provided between the insulation film IL2 and the insulation film IL3; and a third electrode 13 provided on a second insulation film 22. In addition, the capacitor 100 includes: a first insulation film 21 formed in a part of the insulation film IL2; a third insulation film 23 formed in a part of the insulation film (inorganic insulation film) IL1; and the second insulation film 22 formed as the same film as an insulation film TGI in a top-gate oxide semiconductor transistor.

The capacitor 100 has a multilayer structure including: the first electrode 11 as a gate electrode; the second electrode 12; and the third electrode 13 as a top-gate electrode.

In the pixel circuit board 200, the first electrode 11 and the second electrode 12 are prevented from being short-circuited as detailed later, by specifying, in the capacitor 100, the first insulation film 21 to have a lower etching rate to a prescribed etchant than does the second insulation film 22.

The pixel circuit board 200 includes, for example, a top-gate transistor including the semiconductor film SC, and the semiconductor film SC is, for example, a polysilicon semiconductor film. This top-gate transistor is preferably obtained by designing the first electrode 11 of the capacitor 100 as the gate electrode of the top-gate transistor and connected electrically to a high electrical potential supply line (not shown) via the third electrode 13. The top-gate transistor is connected electrically to an anode E1 in the light-emitting element layer 300 via a metal film MS. In the pixel circuit board 200, the top-gate transistor including the semiconductor film SC can function as a light-emission control transistor. A part of the metal film MS shown in FIG. 1 may be a dummy.

In addition, the pixel circuit board 200 includes a top-gate oxide semiconductor transistor including an oxide semiconductor film SZ and a top-gate electrode TGE, and the top-gate insulation film TGI in this oxide semiconductor transistor is formed as the same layer as the second insulation film 22. The oxide semiconductor transistor may be, for example, connected electrically to a control terminal (gate terminal) and an initialization signal line (not shown) of the transistor including the semiconductor film SC via a metal film MT. In the pixel circuit board 200, the top-gate transistor including the oxide semiconductor film SZ can function as an initialization transistor.

The oxide semiconductor film SZ needs, for example, only to contain an oxide containing at least one of indium (In), gallium (Ga), and zinc (Zn) and may contain indium gallium zinc oxide (InGaZnO). Alternatively, the oxide semiconductor film SZ may contain at least one of silicon oxide (SiOx), silicon nitride (SiNx), and silicon oxynitride (SiNOx). Silicon oxide (SiO) is made from a gaseous mixture containing silane (SiH₄) and oxygen (O₂) by vapor phase epitaxy. Silicon nitride (SiN) is made from a gaseous mixture containing silane (SiH₄), ammonia (NH₃), and nitrogen (N₂). Silicon oxynitride is made from a gaseous mixture containing silane (SiH₄), ammonia (NH₃), oxygen (O₂), and nitrogen (N₂).

The light-emitting element layer 300 includes a plurality of light-emitting elements EL including an anode E1, a cathode E2, and an EL layer and may include a sealing layer (not shown). The anode E1 may be a pixel electrode divided by an insulating bank BK, and the cathode E2 may be a common electrode that is common to the plurality of light-emitting elements EL.

The light-emitting elements EL need only to include a plurality of light-emitting elements each including an OLED (light-emitting diode including an organic light-emitting layer) layer or a QLED (light-emitting diode containing luminous quantum dots) layer.

### Display Device 501

FIG. 2 is a schematic cross-sectional view of a display device 501 in accordance with an aspect of the present disclosure. The display device 501 in accordance with an aspect of the present disclosure includes a pixel circuit board 201 in accordance with an aspect of the present disclosure and the light-emitting element layer 300 disposed on the pixel circuit board.

Referring to FIG. 2, the pixel circuit board 201 includes: a capacitor 100′ in the first pixel circuit; the undercoat film 41, the semiconductor film SC, the gate insulation film GI, the insulation film IL1, the insulation film IL2, and the insulation film IL3, all formed on the main substrate 40; and the organic insulation film (alternatively referred to as the “planarization film”) 42 formed on the insulation film IL3. Here, the capacitor 100′ includes: a first electrode 11′ provided on the insulation film IL1; and a second electrode 12′ provided on the insulation film IL3. In addition, in the capacitor 100′, the first insulation film 21 is formed in a part of the insulation film IL2, the third insulation film 23 is formed in a part of the insulation film IL1, the second insulation film 22 is formed in a part of the insulation film IL3, and the third insulation film 23 is formed as the same film as the insulation film TGI in a top-gate oxide semiconductor transistor. Note that members that have the same function are denoted by the same reference numeral, and description thereof is omitted.

A capacitor 101 has a multilayer structure including the first electrode 11′, the second electrode 12′ as a top-gate electrode, and a gate electrode GE.

In the pixel circuit board 201, the first electrode 11′ and the second electrode 12′ are prevented from being short-circuited as detailed later, by specifying, in the capacitor 100′, the first insulation film 21 to have a lower etching rate to a prescribed etchant than does a second insulation film 22′.

In the pixel circuit board 201, the capacitor 100′ needs only to include, as an electrode, the gate electrode GE of a transistor that includes the semiconductor film SC and to be connected electrically to a high electrical potential supply line (not shown).

In addition, the pixel circuit board 201 includes a top-gate oxide semiconductor transistor including the oxide semiconductor film SZ and the top-gate electrode TGE, and the top-gate insulation film TGI in this oxide semiconductor transistor is formed as the same layer as the second insulation film 22′. The insulation film IL2 may be partially formed as the same layer as a first insulation film 21′ between the top-gate electrode TGE and the top-gate insulation film TGI, and this insulation film IL2 may partially constitute a part of the gate insulation film in the oxide semiconductor transistor. Alternatively, no insulation film IL2 may be provided between the top-gate electrode TGE and the top-gate insulation film TGI.

A description is given below of a specific mode of the capacitor included in the pixel circuit board in accordance with an aspect of the present disclosure.

### Capacitor (Capacitive Element) 101

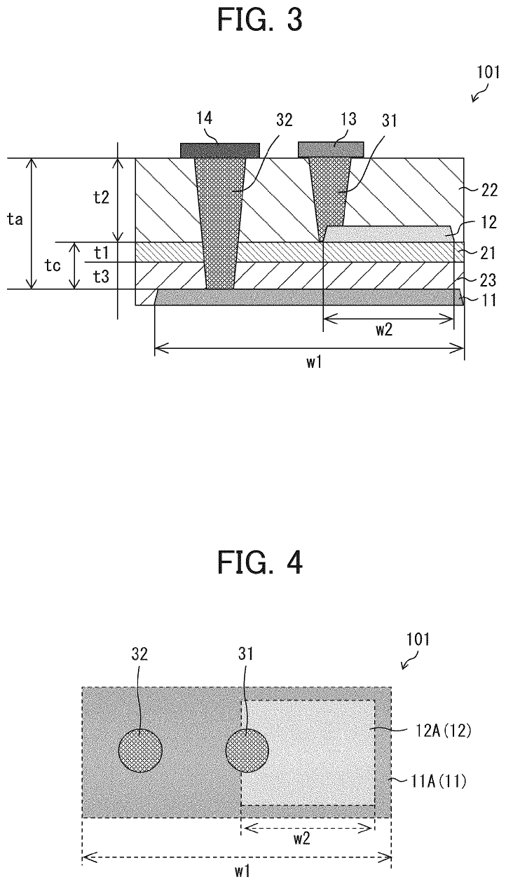

Referring to FIG. 3, the capacitor (capacitive element) 101 includes the first electrode 11, the second electrode 12, the third electrode 13, and a fourth electrode 14 as electrodes and further includes the first insulation film 21, the second insulation film 22, and the third insulation film 23 as insulation films.

In the capacitor 100, the first electrode 11 is formed in an underlying layer of the first insulation film 21, and the second electrode 12 is formed on the first insulation film 21. In addition, the third electrode 13 and the fourth electrode 14 are formed in an overlying layer of the second insulation film 22, the second electrode 12 and the third electrode 13 are connected together via a first contact hole 31 that runs through the second insulation film 22, and the first electrode 11 and the fourth electrode 14 are connected together via a second contact hole 32 that runs through the first insulation film 21, the second insulation film 22, and the third insulation film 23. Hence, the capacitor 100 forms capacitance (electrostatic capacity) between the first electrode 11 and the second electrode 12.

In the capacitor 100, the etching rate of the first insulation film 21 to a prescribed etchant is lower than the etching rate of the second insulation film 22, which is disposed in an overlying layer of the first insulation film 21, to the same etchant. Hence, even if the etchant is supplied to locations where a part of the edge region of the first contact hole 31 fails to sit on the second electrode 12, the first contact hole 31 takes additional time to be formed through the insulation films 21, 22, and 23 due to the first insulation film 21. Design alignment for contact holes can be hence increased in designing capacitors, which in turn enables designing a high-definition pixel circuit board.

Each of the first electrode 11, the second electrode 12, the third electrode 13, and the fourth electrode 14 need only to contain a conductive material such as titanium (Ti) or aluminum (Al), and these electrodes need only to be formed by a publicly known method such as sputtering.

The etching rate of the insulating material contained in the first insulation film 21 should not be limited so long as the etching rate of the insulating material contained in the first insulation film 21 is lower than the etching rate of the insulating material contained in the second insulation film 22. Nonetheless, when a fluorine-based gas (e.g., PFC) is used as the prescribed etchant, and the etching is done by dry etching, for example, the etching rate of the insulating material contained in the first insulation film 21 is preferably in the range of from 0 nm/minute exclusive to 120 nm/minute inclusive and more preferably in the range of from 0 nm/minute exclusive to 60 nm/minute inclusive. Since the etching rate of the insulating material contained in the first insulation film 21 is lower in the range of from 0 nm/minute exclusive to 120 nm/minute inclusive, a difference can be increased between (i) the time taken to form the first contact hole 31 through the second insulation film 22 which has a thickness t2 and (ii) the time taken to form the second contact hole 32 through the first, second, and third insulation films 21, 22, 23 which have a combined thickness ta, both the first contact hole 31 and the second contact hole 32 being provided between the first electrode 11 and the third electrode 13 (and the fourth electrode 14) shown in FIG. 1. Hence, even if a part of the edge region of the first contact hole 31 fails to sit on the second electrode 12 in forming the first contact hole 31 and the second contact hole 32 by, for example, a publicly known etching method as shown in FIG. 3, the temporal margin for the etchant for forming the first contact hole 31 to reach the first electrode 11 can be increased. Thus, the risk can be reduced of the first contact hole 31 coming into contact with the first electrode 11 and of the capacitor 101 being short-circuited. Therefore, the design alignment for the first contact hole 31 and the second contact hole 32 can be increased. As a result, referring to FIG. 4, an area 11A of the first electrode 11 in a top view and an area 12A of the second electrode 12 in a top view can be decreased in the capacitor 101. Thus, the capacitor 101 can be manufactured with higher definition.

In addition, for example, a width w1 of the first electrode 11 and a width w2 of the second electrode 12 can be decreased in the plan view shown in FIG. 3. As an example, the width w1 of the first electrode 11 needs only to be larger than the width w2 of the second electrode 12 and is by no means limited. Nonetheless, the width w1 needs only to be in the range of, for example, from 0.01 μm to 20 μm and is more preferably in the range of from 0.1 μm to 10 μm. In addition, as an example, the width w2 of the second electrode 12 needs only to be smaller than the width w1 of the first electrode 11 and is by no means limited. Nonetheless, the width w2 needs only to be in the range of, for example, from 0.01 μm to 20 μm and more preferably in the range of from 0.1 μm to 10 μm. The capacitor 101 may be designed so that the width w1 of the first electrode 11 is in the range of from 0.01 μm to 20 μm and the width w2 of the second electrode 12 is in the range of from 0.01 μm to 20 μm.

The etching rate of the insulating material contained in the second insulation film 22 is preferably in the range of from 120 nm/minute to 600 nm/minute and more preferably in the range of from 180 nm/minute to 600 nm/minute, and, in these ranges, the etching time for forming the first contact hole 31 can be further reduced when increased in the range of from 120 nm/minute to 600 nm/minute.

Since the third insulation film 23 may be made from the same insulating material as the second insulation film 22 as detailed later, and the etching rate of the insulating material contained in the third insulation film 23 is equal to the etching rate of the insulating material contained in the second insulation film 22, description thereof is omitted.

The capacitance of the capacitor 101 is designed by considering (1) the area 11A of the first electrode 11 in a top view and the area 12A of the second electrode 12 in a top view, (2) a thickness t1 of the first insulation film 21 and a thickness t3 of the third insulation film 23, both provided between the first electrode 11 and the second electrode 12, and (3) the type of the insulating material contained in the first insulation film 21 and the type of the insulating material contained in the third insulation film.

In the capacitor 101, the difference between the etching time required to form the first contact hole 31 and the etching time taken to form the second contact hole 32 needs only to be designed by adjusting the etching rate of the first insulation film 21 to the prescribed etchant and the thickness t1 of the first insulation film 21. In addition, the capacitance of the capacitor 101 needs only to be designed by considering the thickness t1 and the type of the insulating material contained in the first insulation film 21 and the thickness t3 and the type of the insulating material contained in the third insulation film 23. The capacitance of this capacitor may be designed by considering a combined thickness tc of the thickness t1 of the insulating material and the thickness t3 of the insulating material between the first electrode 11 and the second electrode 12.

In addition, when the first electrode 11 is a gate electrode, and the third electrode 13 is a top-gate electrode, as in the case of the pixel circuit board 200 shown in FIG. 1, the capacitance of the capacitor 101 should be designed by considering the area of the third electrode 13 in a top view, the thickness t2 of the second insulation film 22, and the type of the insulating material contained in the second insulation film 22.

The capacitor included in the pixel circuit board in accordance with an aspect of the present disclosure, which should not be limited, may have an electrostatic capacity of, for example, approximately from 0.1 to 1,000 fF (femtofarad) and preferably from 1 to 100 fF (femtofarad).

The thickness t1 of the first insulation film 21 is preferably in the range of from 1 nm to 200 nm and more preferably in the range of from 10 nm to 100 nm. The thickness t1 of the first insulation film 21, when increased in the range of from 1 nm to 200 nm, can increase etching time for the first insulation film 21 and increase design alignment for the contact holes 31 and 32.

The thickness t2 of the second insulation film 22 is preferably in the range of from 10 nm to 1,000 nm and more preferably in the range of from 100 nm to 800 nm. The thickness t2 of the second insulation film 22, when reduced in the range of from 10 nm to 1,000 nm, can reduce etching time for the second insulation film 22 and increase design alignment for the contact holes 31 and 32.

The thickness t3 of the third insulation film 23 is preferably in the range of from 1 nm to 1,000 nm and more preferably in the range of from 10 nm to 500 nm. Since the thickness t3 of the third insulation film 23 is in the range of from 1 nm to 1,000 nm, the capacitance of the capacitor 101 needs only to designed between the first electrode 11 and the second electrode 12 in combination with the first insulation film 21.

As described in the foregoing, to increase design alignment for the contact holes 31 and 32, for example, the combination of the first insulation film 21 and the second insulation film 22 is preferably such that the first insulation film 21 is selected from at least one of a silicon nitride film, an aluminum oxide film, a lanthanum oxide film, a hafnium oxide film, and a gadolinium oxide film and the second insulation film 22 contains, for example, a silicon oxide film.

As described in the foregoing, to increase design alignment for the contact hole, for example, the combination of the first insulation film 21 and the second insulation film 22 is preferably such that the first insulation film 21 is selected from at least one of a silicon nitride film, an aluminum oxide film, a lanthanum oxide film, a hafnium oxide film, and a gadolinium oxide film and the second insulation film 22 contains a silicon oxide film.

The silicon nitride film, the aluminum oxide film, the lanthanum oxide film, the hafnium oxide film, and the gadolinium oxide film, as well as the silicon oxide film, need only to be formed by, for example, a publicly known method such as plasma chemical gas phase deposition (CVD), and, for example, the etching rate may be adjusted to fall in the above-described range depending on manufacturing conditions of the film of these insulating materials. In addition, the film of these insulating materials may be adjusted in dielectric constant and in insulation depending on manufacturing conditions.

Note that the conductive material with which the contact holes 31 and 32 are filled is, for example, molybdenum (Mo), copper (Cu), aluminum (Al), or tungsten (W).

Either one of the third electrode 13 and the fourth electrode 14 needs only to be connected electrically to, for example, a high electrical potential supply line (not shown) or a gate electrode of a drive transistor (not shown).

### Capacitor 102

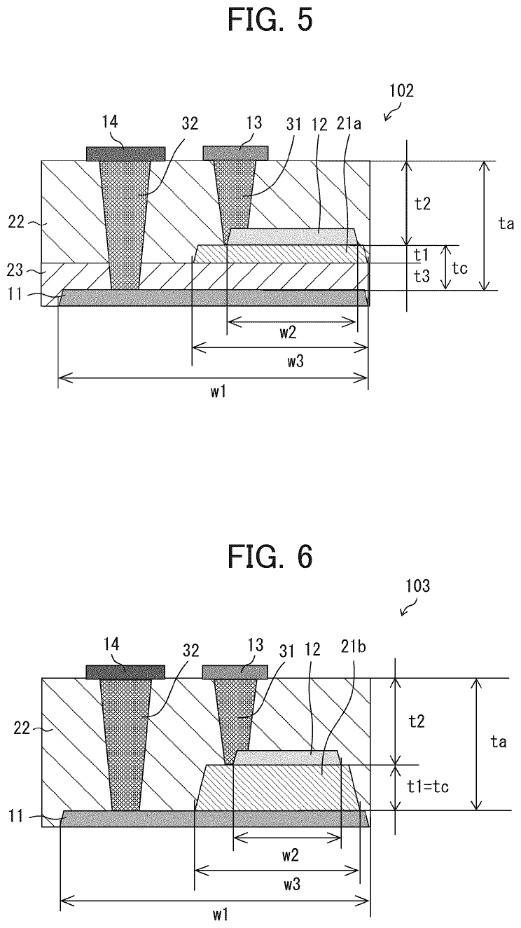

The capacitor included in the pixel circuit board in accordance with an aspect of the present disclosure is not necessarily limited to the aforementioned mode. For example, referring to FIG. 5, a capacitor (capacitive element) 102 includes the first electrode 11, the second electrode 12, the third electrode 13, and the fourth electrode 14 as electrodes and a first insulation film 21a, the second insulation film 22, and the third insulation film 23 as insulation films.

In the capacitor 102, the first electrode 11 is formed in an underlying layer of the first insulation film 21a, and the second electrode 12 is formed on the first insulation film 21a. In addition, in the capacitor 102, the third electrode 13 and the fourth electrode 14 are formed in the overlying layer of the second insulation film 22, the second electrode 12 and the third electrode 13 are connected together via the first contact hole 31 which runs through the second insulation film 22, the first electrode 11 and the fourth electrode 14 are connected together via the second contact hole 32 which runs through the second insulation film 22 and the third insulation film 23, and here, the second contact hole 32 is not formed so as to run through the first insulation film 21a which is formed insularly on the third insulation film 23.

In the capacitor 102, the etching rate of the first insulation film 21a is lower than the etching rate of the second insulation film 22, which is disposed in an overlying layer of the first insulation film 21a, to the same etchant. Hence, even if the etchant is supplied to locations where a part of the edge region of the first contact hole 31 fails to sit on the second electrode 12, the first contact hole 31 takes additional time to be formed through the insulation films 21a, 22, and 23 due to the first insulation film 21a.

Since the etching rate, the thickness t1, and the type of the insulating material for the first insulation film 21a are the same as those for the capacitor 101, description thereof is omitted.

A width w3 of the first insulation film 21a needs only to be smaller than the width w1 of the first electrode 11 and larger than the width w2 of the second electrode 12 and is by no means limited. Nonetheless, the width w3 needs only to be in the range of, for example, from 0.01 μm to 20 μm and is more preferably in the range of from 0.1 μm to 10 μm. This particular structure enables increasing the time for the etchant for the contact hole 31 formed so as not to sit squarely on the second electrode 12 to reach the first electrode 11. Thus, alignment can be increased in designing the contact hole 31 and the contact hole 32, which enables the pixel circuit board including the capacitor 102 to have higher definition.

Similarly to the width w3 of the first insulation film 21a, the area of the first insulation film 21a in a top view needs only to be smaller than the area 11A of the first electrode 11 in a top view and larger than the area 12A of the second electrode 12 in a top view, as shown in FIG. 4.

In addition, when the first electrode 11 is a gate electrode, and the third electrode 13 is a top-gate electrode, the capacitance of the capacitor 101 should be designed by further considering the area of the third electrode 13 in a top view, the thickness t2 of the second insulation film 22, and the type of the insulating material contained in the second insulation film 22. This is commonly true for capacitors included in the pixel circuit board in accordance with an aspect of the present disclosure.

In the capacitor 102, the width w3 of the first insulation film 21a needs only to be smaller than the width w1 of the first electrode 11 and larger than the width w2 of the second electrode 12 and is by no means limited. Nonetheless, the width w3 needs only to be in the range of, for example, from 0.01 μm to 20 μm and is more preferably in the range of from 0.1 μm to 10 μm. Here, by increasing the width w3 of the first insulation film 21a in the range of from 0.01 μm to 20 μm, the first insulation film 21a can successfully prevent the contact hole 31 from failing to sit squarely on the second electrode 12 and hence reaching the first electrode 11, which enables increasing the time for the etchant for the contact hole 31 formed so as not to sit squarely on the second electrode 12 to reach the first electrode 11. In addition, in the capacitor 102, the contact hole 32 can be formed so as not to come into contact with the first insulation film 21a when the width w3 of the first insulation film 21a is decreased in the range of from, for example, 0.01 μm to 20 μm. Thus, alignment can be increased in designing the contact hole 31 and the contact hole 32, which enables the pixel circuit board including the capacitor 102 to have higher definition.

### Capacitor 103

The capacitor included in the pixel circuit board in accordance with an aspect of the present disclosure is not necessarily limited to the aforementioned mode. For example, referring to FIG. 6, a capacitor 103 includes the first electrode 11, the second electrode 12, the third electrode 13, and the fourth electrode 14 as electrodes and a first insulation film 21b and the second insulation film 22 as insulation films.

In the capacitor 103, the first electrode 11 is formed in an underlying layer of the first insulation film 21b, and the second electrode 12 is formed on the first insulation film 21b. In addition, in the capacitor 103, the third electrode 13 and the fourth electrode 14 are formed in the overlying layer of the second insulation film 22, the second electrode 12 and the third electrode 13 are connected together via the first contact hole 31 which runs through the second insulation film 22, the first electrode 11 and the fourth electrode 14 are connected via the second contact hole 32 which runs through the second insulation film 22, and here, the second contact hole 32 is not formed so as to run through the first insulation film 21b which is formed insularly on the first electrode 11.

In the capacitor 103, the etching rate of the first insulation film 21b is lower than the etching rate of the second insulation film 22, which is disposed in the overlying layer of the first insulation film 21b, to the same etchant. Hence, even if the etchant is supplied to locations where a part of the edge region of the first contact hole 31 fails to sit on the second electrode 12, the first insulation film 21b can increase the time required to form the first contact hole 31 through the insulation films 21b, 22, thereby enabling quickly forming the second contact hole 32 through the second insulation film 22.

Since the etching rate, the thickness t1, the width w3, and the type of the insulating material for the first insulation film 21b are the same as those for the capacitor 102, description thereof is omitted.

In the capacitor 103, the width w3 of the first insulation film 21b needs only to be smaller than the width w1 of the first electrode 11 and larger than the width w2 of the second electrode 12 and is by no means limited. Nonetheless, the width w3 needs only to be in the range of from, for example, 0.01 μm to 20 μm and is more preferably in the range of from 0.1 μm to 10 μm. This particular structure enables increasing the time for the etchant for the contact hole 31 formed so as not to sit squarely on the second electrode 12 to reach the first electrode 11. Thus, alignment can be increased in designing the contact hole 31 and the contact hole 32, which enables the pixel circuit board including the capacitor 103 to have higher definition.

In addition, in the capacitor 103, similarly to the width w3 of the first insulation film 21b, the area of the first insulation film 21b in a top view needs only to be smaller than the area 11A of the first electrode 11 in a top view and larger than the area 12A of the second electrode 12 in a top view, as shown in FIG. 4.

The capacitor 103 includes no third insulation film 23. In the capacitor 103, the thickness t1 of the first insulation film 21b corresponds to the thickness tc of the film of the insulating material between the first electrode 11 and the second electrode 12, and the etching time for forming the contact holes 31 and 32 and the electrostatic capacity between the first electrode 11 and the second electrode 12 need only to be adjusted by adjusting the thickness tc.

In addition, the capacitor 103 allows, for example, simultaneously forming the first and second contact holes 31 and 32 by designing the type and the thickness t1 of the insulating material contained in the first insulation film 21b and the type and the thickness ta of the insulating material contained in the second insulation film 22.

### Capacitor 104

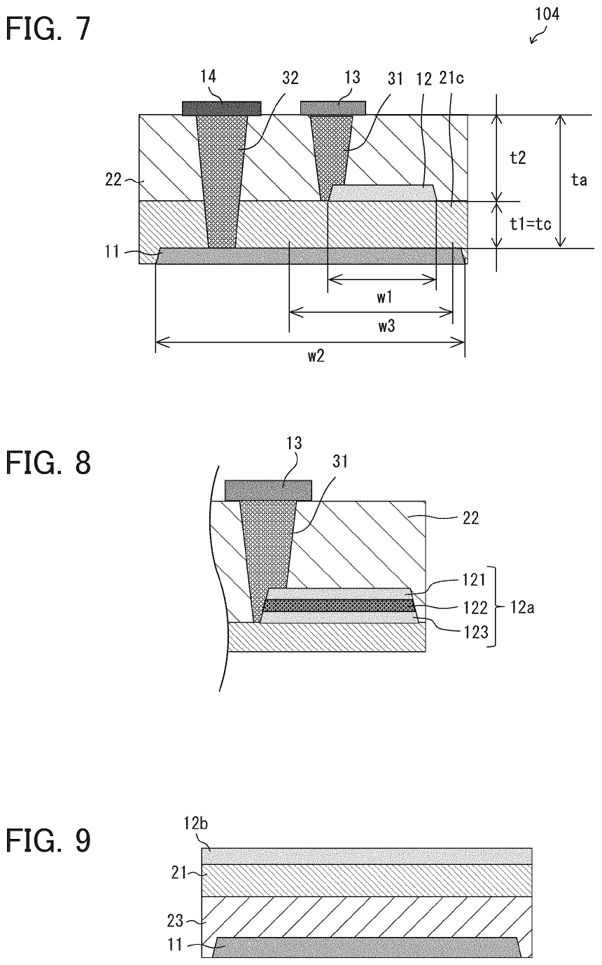

The capacitor included in the pixel circuit board in accordance with an aspect of the present disclosure is not necessarily limited to the aforementioned mode. For example, referring to FIG. 7, a capacitor 104 includes the first electrode 11, the second electrode 12, the third electrode 13, and the fourth electrode 14 as electrodes and a first insulation film 21c and the second insulation film 22 as insulation films.

In addition, in the capacitor 104, the first electrode 11 is formed in an underlying layer of the first insulation film 21c, and the second electrode 12 is formed on the first insulation film 21c. In addition, in the capacitor 104, the third electrode 13 and the fourth electrode 14 are formed in the overlying layer of the second insulation film 22, the second electrode 12 and the third electrode 13 are connected together via the first contact hole 31 which runs through the second insulation film 22, and the first electrode 11 and the fourth electrode 14 are connected together via the second contact hole 32 which runs through a second insulation film 22c.

In the capacitor 104, the etching rate of the first insulation film 21c is lower than the etching rate of the second insulation film 22, which is disposed in an overlying layer of the first insulation film 21c, to the same etchant. Hence, even if the etchant is supplied to locations where a part of the edge region of the first contact hole 31 fails to sit on the second electrode 12, the first insulation film 21c can increase the time required to form the first contact hole 31 through the insulation film 21c.

Since the etching rate, the thickness t1, the width w3, and the type of the insulating material for the first insulation film 21c are the same as those for the capacitor 103, description thereof is omitted.

In the capacitor 104, similarly to the capacitor 103, the thickness t1 of the first insulation film 21c corresponds to the thickness tc of the film of the insulating material between the first electrode 11 and the second electrode 12, and the etching time for forming the contact holes 31 and 32 and the electrostatic capacity between the first electrode 11 and the second electrode 12 need only to be adjusted by adjusting the thickness tc.

### Variation Examples

The capacitor included in the pixel circuit board in accordance with an aspect of the present disclosure is not necessarily limited to the aforementioned mode. A capacitor included in a pixel circuit board in accordance with a variation example may include a second electrode 12a shown in FIG. 8, in place of the second electrode included in any of the capacitors 101, 102, 103, and 104 described above, and the second electrode 12a may include a laminate film with a multilayer structure that includes a stack of metal films 121, 122, and 123.

The second electrode 12a has an edge region that may be etched by an etchant when the second electrode 12a is formed on the first insulation film 21 by patterning through photolithography and etching. Due to this etching, the second electrode 12a may come to have such an upwardly tapered outer peripheral portion on the end faces of the metal films 121, 122, 123 from the top-face side of the second electrode 12a.

In the second electrode 12a, each of the metal films 121 and 123 may be made of a metal such as titanium (Ti) or molybdenum (Mo), and the metal film 122 may be made of aluminum (Al). The second electrode 12a, by including the metal film 121 on its top, addresses otherwise possible improper contacts with the conductive material filling the contact hole, and by including the metal film 122, exhibits increased electrical conductivity between the second electrode 12a and the conductive material filling the contact hole.

### Other Modes

Note that the capacitor included in the pixel circuit board in accordance with an aspect of the present disclosure is not necessarily limited to the aforementioned mode. For example, the pixel circuit board in accordance with an aspect of the present disclosure may include a plurality of first and second pixel circuits, have a first contact hole on an end face of the first electrode in at least one of the pixel circuits (first pixel circuit), and have a first contact hole on a top face of the first electrode in another pixel circuit (second pixel circuit).

### Method of Manufacturing Pixel Circuit Board

Referring to FIGS. 9 to 12, a method of manufacturing the pixel circuit board in accordance with an aspect of the present disclosure involves: a step of forming the first electrode 11; a step of forming the first insulation film 21 on the first electrode 11; a step of forming a second electrode 12b on the first insulation film 21; a step of forming the second insulation film 22 on the second electrode 12b; a step of forming the first contact hole 31 overlapping the second electrode 12 in a plan view by etching the second insulation film 22 using an etchant; and a step of forming the second contact hole 32 overlapping the first electrode 11 in a plan view by etching the second insulation film 22 using the etchant, wherein the first insulation film has a lower etching rate to the etchant than does the second insulation film.

FIG. 9 shows an intermediate body for a pixel circuit board formed by the step of forming the first electrode 11, the step of forming the first insulation film 21 on the first electrode 11, and the step of forming a second electrode 12b on the first insulation film 21. This intermediate body is provided with the third insulation film 23 between the first electrode 11 and the first insulation film 21 between the step of forming the first electrode 11 and the step of forming the first insulation film 21 on the first electrode 11 (a step of forming a third insulation film). The first electrode 11 may be formed, for example, on a gate insulation film (not shown) included in the substrate.

In the step of forming the first electrode 11 and the step of forming the second electrode 12b on the first insulation film 21, each of the first electrode 11 and the second electrode 12b may be formed by a publicly known physical deposition method such as sputtering, vacuum vapor deposition, or ion plating. Note that each of the first electrode 11 and the second electrode 12b may be formed so as to have a multilayer structure of, for example, a titanium layer and an aluminum layer.

In addition, in the step of forming the first insulation film 21 on the first electrode 11, the first insulation film 21 may be formed by, for example, a film-forming method such as plasma chemical gas phase deposition (CVD) and sintering as a silicon nitride film, an aluminum oxide film, a lanthanum oxide film, a hafnium oxide film, and a gadolinium oxide film. For example, silicon oxide (SiO) is made from a gaseous mixture containing silane (SiH₄) and oxygen (O₂) by vapor phase epitaxy. A silicon nitride film (SiN) is made from a gaseous mixture containing silane (SiH₄), ammonia (NH₃), and nitrogen (N₂). A silicon oxynitride film may be made from a gaseous mixture containing silane (SiH₄), ammonia (NH₃), oxygen (O₂), and nitrogen (N₂). In addition, an aluminum oxide film may be made of a metal alkoxide of aluminum (Al) and a gaseous mixture containing oxygen (O₂) and/or nitrogen (N₂). A lanthanum oxide film, a hafnium oxide film, and a gadolinium oxide film may be made by applying and sintering an organic solvent containing an oxide film material.

The etching rate of the first insulation film 21 may be adjusted by adjusting, for example, film-formation temperatures, sintering temperatures, and/or other conditions in the step of forming the first insulation film 21 on the first electrode 11.

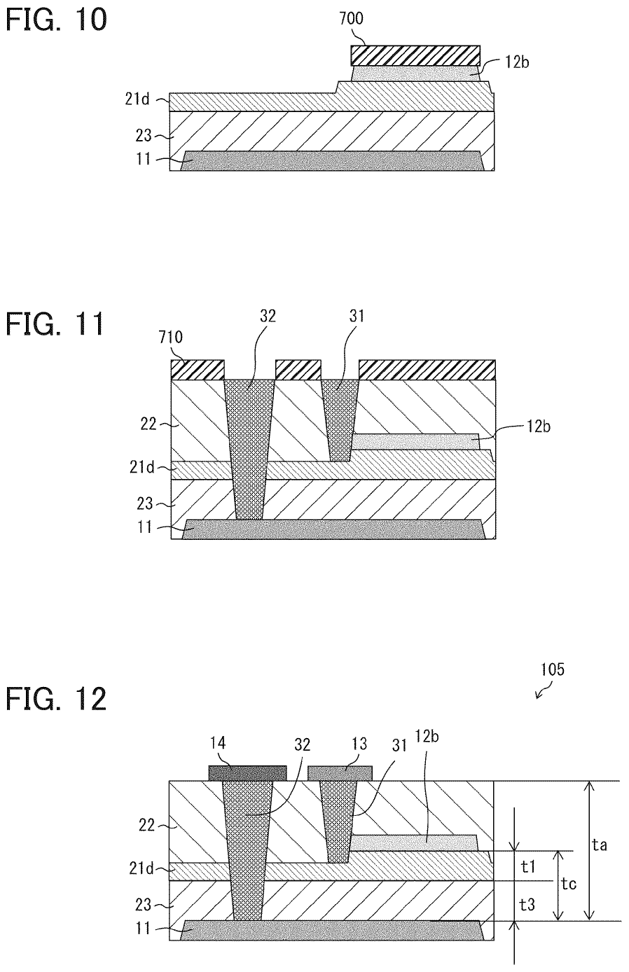

Referring to FIG. 10, a method of manufacturing the pixel circuit board in accordance with an aspect of the present disclosure involves a step of etching the second electrode 12b covered with a resist 700 between the step of forming the second electrode 12b and the step of forming the second insulation film 22.

If the second electrode 12b covered with the resist 700 is etched, the periphery of the second electrode 12b could be etched out together with the second electrode 12b and reduced in thickness in a first insulation film 21d, as shown in FIG. 10. The method of manufacturing the pixel circuit board in accordance with an aspect of the present disclosure, by providing the second electrode 12b on the first insulation film 21d which has a low etching rate, enables not only preventing short-circuiting in forming contact holes (detailed later), but also preventing the periphery of the second electrode 12b from being reduced in thickness as in the case of the first insulation film 21d.

Referring to FIG. 11, the method of manufacturing the pixel circuit board in accordance with an aspect of the present disclosure forms the second insulation film 22 by the step of forming the second insulation film 22 on the second electrode 12b and etches this second insulation film 22 using an etchant.

In the step of forming the second insulation film 22, in the same manner as in the step of forming the first insulation film 21, for example, the second insulation film 22 may be formed by, for example, plasma chemical gas phase deposition (CVD) and sintering as a silicon oxide film, a silicon nitride film, an aluminum oxide film, a lanthanum oxide film, a hafnium oxide film, and a gadolinium oxide film and preferably as a silicon oxide film. A silicon oxide film is made from a gaseous mixture containing silane (SiH₄) and oxygen (O₂) by vapor phase epitaxy, as described earlier.

In the step of forming the second insulation film 22, the etching rate of the second insulation film 22 may be adjusted to be larger than the etching rate of the first insulation film 21d, by adjusting, for example, the gas mixing ratio, temperature, and/or other conditions in CVD.

Referring to FIG. 11, the method of manufacturing the pixel circuit board in accordance with an aspect of the present disclosure forms the second insulation film 22 by the step of forming the second insulation film 22 on the second electrode 12b and etches this second insulation film 22 using an etchant. The etching may be either dry etching or wet etching, but preferably dry etching such as plasma etching to reduce the possibility of the etchant corroding electrodes.

The etchant used in the etching may be, for example: a noble gas such as argon (Ar) or helium (He); a halogenated carbon gas such as perfluorocarbon gas (PFC) or hydrofluorocarbon gas (HFC); a hydrocarbon gas such as methane; hydrofluoric acid (HF); a chlorine gas; an oxygen gas; or a hydrogen gas. The prescribed etchant may preferably be PFC. Note that the “prescribed etchant” is intended to refer to the etchant used commonly to form contact holes in the first, second, and third insulation films and is not necessarily limited to mean PFC.

In addition, in each of the step of forming the first contact hole 31 and the step of forming the second contact hole 32, conditions other than the time required for etching, such as the etchant supply rate, temperatures, and other conditions, may be designed, for example, by considering, for example, the type of the insulating material contained in the first insulation film 21 and the second insulation film 22 and the type of the etchant used. The etchant supply rate, temperatures, and other conditions may be the same in the step of forming the first contact hole 31 and in the step of forming the second contact hole 32. In the method of manufacturing the pixel circuit board in accordance with an aspect of the present disclosure, since the etching rate of the first insulation film 21 is designed in advance so as to be lower than the etching rate of the second insulation film 22, the conditions for forming the first contact hole 31 and the second contact hole 32 are rendered advantageously easy to design by, for example, rendering the etchant supply rate and temperatures the same.

Note that the first contact hole 31 and the second contact hole 32 may be either simultaneously formed or continuously, but separately formed.

Referring to FIG. 12, the pixel circuit board in accordance with an aspect of the present disclosure also encompasses a capacitor 105, including the first insulation film 21d, that is manufactured by a method of manufacturing the pixel circuit board in accordance with an aspect of the present disclosure and that has, in the periphery of the second electrode 12b, a thin film portion that has a smaller thickness than a portion overlapping the second electrode 12b due to “rework etching”.

The present disclosure is not limited to the description of the embodiments above and may be altered within the scope of the claims. Embodiments based on a proper combination of technical means disclosed in different embodiments are encompassed in the technical scope of the disclosure. Furthermore, new technical features can be created by combining different technical means disclosed in the embodiments.

1. A pixel circuit board comprising a plurality of pixel circuits each including a first electrode and a second electrode forming a capacitance,
the pixel circuit board further comprising a first insulation film and a second insulation film, wherein
the first electrode is formed in an underlying layer of the first insulation film,
the second electrode is formed on the first insulation film,
the second insulation film is formed on the second electrode,
the first insulation film has a lower etching rate to a prescribed etchant than does the second insulation film, and
a first contact hole overlapping the second electrode in a plan view and a second contact hole overlapping the first electrode in a plan view are formed in the second insulation film.

2. The pixel circuit board according to claim 1, wherein
a third electrode is formed in an overlying layer of the second insulation film, and
the second electrode and the third electrode are connected via the first contact hole running through the second insulation film.

3. The pixel circuit board according to claim 2, wherein
a fourth electrode is formed in the overlying layer of the second insulation film, and
the first electrode and the fourth electrode are connected via the second contact hole.

4. The pixel circuit board according to claim 3, wherein the second contact hole runs through the first insulation film and the second insulation film.

5. The pixel circuit board according to claim 1, further comprising a third insulation film, wherein the first insulation film is formed on the first electrode via the third insulation film.

6. The pixel circuit board according to claim 1, wherein the second insulation film is in contact with the first electrode and the second electrode.

7. The pixel circuit board according to claim 1, wherein the first insulation film is insular.

8. The pixel circuit board according to claim 1, wherein the first contact hole overlaps an end face of the second electrode in a plan view.

9. The pixel circuit board according to claim 1, wherein the first insulation film includes: an overlapping portion overlapping the second electrode; and a thin film portion that has a smaller thickness than does the overlapping portion.

10. The pixel circuit board according to claim 1, wherein
one of the first insulation film and the second insulation film includes at least one of a silicon nitride film, an aluminum oxide film, a lanthanum oxide film, a hafnium oxide film, and a gadolinium oxide film, and
another one of the first insulation film and the second insulation film is a silicon oxide film.

11. The pixel circuit board according to claim 1, further comprising a top-gate transistor, wherein
one of the first electrode and the second electrode is connected electrically to a gate electrode of the transistor, and
another one of the first electrode and the second electrode is connected electrically to a high electrical potential supply line.

12. The pixel circuit board according to claim 11, wherein the first insulation film is formed on an inorganic insulation film covering the gate electrode of the transistor.

13. The pixel circuit board according to claim 1, further comprising a top-gate oxide semiconductor transistor, wherein the first insulation film is formed in a same layer as a gate insulation film that is in contact with a gate electrode of the oxide semiconductor transistor.

14. The pixel circuit board according to claim 1, wherein the second electrode is upwardly tapered.

15. The pixel circuit board according to claim 14, wherein the second electrode is a laminate film including an aluminum layer.

16. The pixel circuit board according to claim 15, wherein the first contact hole overlaps an end face of the aluminum layer in a plan view.

17. The pixel circuit board according to claim 1, wherein
the plurality of pixel circuits include a first pixel circuit and a second pixel circuit,
in the first pixel circuit, the first contact hole overlaps an end face of the second electrode in a plan view, and
in the second pixel circuit, the first contact hole overlaps no end face of the second electrode in a plan view.

18. A display device comprising:
the pixel circuit board according to claim 1; and
a light-emitting element layer disposed on the pixel circuit board.

19. A method of manufacturing a pixel circuit board including a pixel circuit including a first electrode and a second electrode forming a capacitance, the method comprising:
a step of forming the first electrode;
a step of forming a first insulation film on the first electrode;
a step of forming the second electrode on the first insulation film;
a step of forming a second insulation film on the second electrode;
a step of forming a first contact hole overlapping the second electrode in a plan view by etching the second insulation film using an etchant; and
a step of forming a second contact hole overlapping the first electrode in a plan view by etching the second insulation film using another etchant, wherein
the first insulation film has a lower etching rate to the etchants than does the second insulation film.

20. The method according to claim 19, further comprising a step of etching the second electrode covered with a resist between the step of forming the second electrode and the step of forming the second insulation film.
